(19) United States
(12) Patent Application Publication
(10) Pub. No.: US 2005/0067143 A1
(43) Pub. Date: Mar. 31, 2005

(54) Heat conductive seat with liquid

(75) Inventors: Rong-Fung Huang, Taipei City (TW); Pei-Sung Tsai, Changhua County (TW); Yue-Jing Dou, Chiayi City (TW)

Correspondence Address: BACON & THOMAS, PLLC, 625 SLATERS LANE, FOURTH FLOOR, ALEXANDRIA, VA, 22314, US

(73) Assignee: Glacialtech, Inc., Junghe City (TW)

(21) Appl. No.: 10/656,275

(22) Filed: Sep. 8, 2003

(51) Int. Cl. H05K 7/20

(52) U.S. Cl. 165/80.3; 165/104.33

(57) ABSTRACT

The conductive seat has parallelly arranged strip members in a bottom area of its base sealed therein with liquid, a plurality of flow channels are formed from and on the bottom of the strip members and are mutually spaced; a return area is formed between the top ends of the strip members and the lid; when the bottom of the base contacts with a heat-generating source, the liquid sealed in the base and absorbing the latent heat from the heat-generating source becomes a vapor flow flowing toward the return area to repeatedly circulate and transmit the heat, thereby the heat is rapidly and uniformly transmitted to the heat sink to further increase the effect of heat sinking.

### BACKGROUND OF THE INVENTION

1. Field of the Invention

The present invention is related to a heat conductive seat with liquid therein, and especially related to a heat conductive member used between a heat-generating source and a heat sink applying the principles of capillarity and heat pipe to fast transmit the heat source formed by the heat-generating source to the heat sink, this can elevate the effect of heat sinking.

2. Description of the Prior Art

Microprocessors (CPU's) used on personal computers nowadays not only shall be developed in pursuance of the requirements of the application fields of Internet and multimedia etc., but also even shall be developed more in pursuance of highly efficient operation of timing pulses for market promotion nowadays; under such a tendency certainly, we shall pay attention more to the feature of heat sinking of a microprocessor itself in designing its packing, so that in high speed operation of the microprocessor, possibility of damage or down state of a system induced by uneasy effusion of large amount of heat can be avoided. Thereby, operating efficiency of a heat sink used for a microprocessor will directly affect the capability of maintaining in a normal range of working temperature of the microprocessor; this further affects normal operation of a personal computer.

The basic structure of a heat sink used on a common microprocessor has a heat-sinking main body with heat-sinking fins made of aluminum (or copper) to contact with a heat-generating source of the microprocessor, in order to transmit heat to the heat-sinking fins, and a fan on the heat-sinking fins generates air flow for heat sinking to make contact of the heat-sinking fins with the flowing air to achieve the goal of heat sinking.

However, no matter the heat-sinking fins of the heat sink are integrally formed of aluminum or of copper, the entire heat sink and the heat-generating source are subjected directly to heat conduction acting therebetween, the heat conducting rate of the material of the heat sink is too low to increase the heat-sinking efficiency; so that the contact area of the heat-sinking fins with the heat-generating source does not have an evident difference of temperature, this reduces the heat transmitting speed and is unable to maintain a due heat-sinking efficiency.

### SUMMARY OF THE INVENTION

The heat conductive seat with liquid of the present invention provides a plurality of strip members in the bottom area of a base having liquid therein using principles of capillarity and heat pipe, flow channels are formed from the strip members on the bottom of the latter and are mutually spaced, a return area is formed between the tops of the strip members and a lid; when in use, the bottom of the base contacts with a heat-generating source, and the top of the base contacts with a heat sink, the liquid sealed in the base and absorbing the latent heat from the heat-generating source becomes a vapor flow flowing toward the return area; when the vapor flow uniformly returns to the contact areas of the heat sink with the top of the base, it condenses by heat discharging into liquid and drops into the flow channels to repeatedly circulate and transmit the heat, and the heat is rapidly and uniformly transmitted to the heat sink to further increase the effect of heat sinking.

Particularly, the strip members are strip-like structure portions with their sections wider in the middles and tapering to the top and bottom ends thereof; so that when the vapor flow flows toward the area with lower temperature on the top of the base, it can be transversely transmitted by the flow channels of the strip members to the area with lower temperature, and the liquid formed by condensing by heat discharging can smoothly drops into the flow channels by having the sectional conformation of the strip members, and rapidly flows to an area of high temperature by the function of capillarity, thereby, an object of transmitting heat to make uniform temperature can be obtained.

The present invention will be apparent in its structural construction and entire operation mode after reading the detailed description of the preferred embodiments thereof in reference to the accompanying drawings.

### BRIEF DESCRIPTION OF THE DRAWINGS

FIG. 1 is a schematic perspective view showing the appearance of the entire of a heat conductive seat of the present invention and its element allocation;

FIG. 2 is an analytic perspective view showing structurally the elements of the heat conductive seat of the present invention;

FIG. 3 is a sectional view showing the capillary structure longitudinally of the present invention;

FIG. 4 is a sectional view showing the capillary structure axially of the present invention;

FIG. 5 is an enlarged schematic sectional view showing the capillary structure of the present invention;

FIG. 6 is an enlarged schematic sectional view showing the capillary structure of another embodiment of the present invention;

FIG. 7 is an enlarged schematic sectional view showing the capillary structure of a further embodiment of the present invention;

FIG. 8 is an enlarged schematic sectional view showing the capillary structure of an even further embodiment of the present invention;

FIG. 9 is an enlarged schematic sectional view showing the conformation and condition of allocation of the strip members of the present invention;

FIG. 10 is a diagram showing a curve of efficiency of heat transmission of the conformation and allocation of the strip members of the present invention.

### DETAILED DESCRIPTION OF THE PREFERRED EMBODIMENT

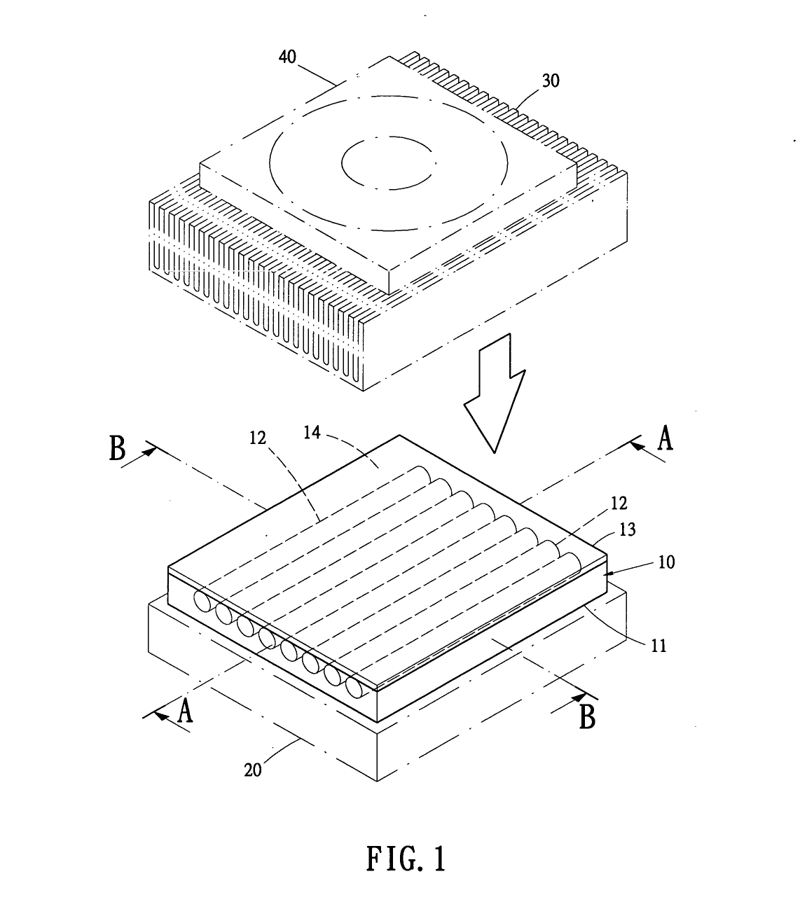

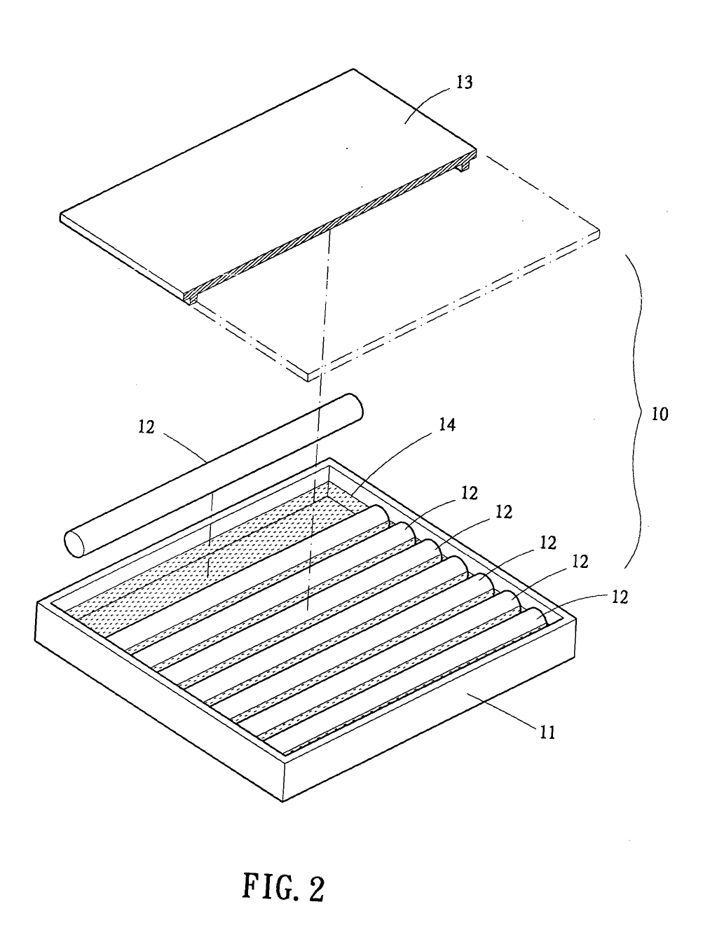

The basic structure of the heat conductive seat with liquid of the present invention is as shown in FIGS. 1 and 2, wherein the heat conductive seat 10 has a recessed box like base 11 as a main body thereof, the base 11 is fixedly provided therein with a plurality of strip members 12, a lid 13 is provided to cover the base 11; the base 11 is sealed therein with liquid 14 composed of water, methanol or cooling medium to form a heat conductive member used between a heat-generating source 20 and a heat sink 30 to fast transmit the heat source to the heat sink 30 uniformly, and a fan 40 is provided on the heat sink 30 to generate air flow to get an object of fast heat sinking.

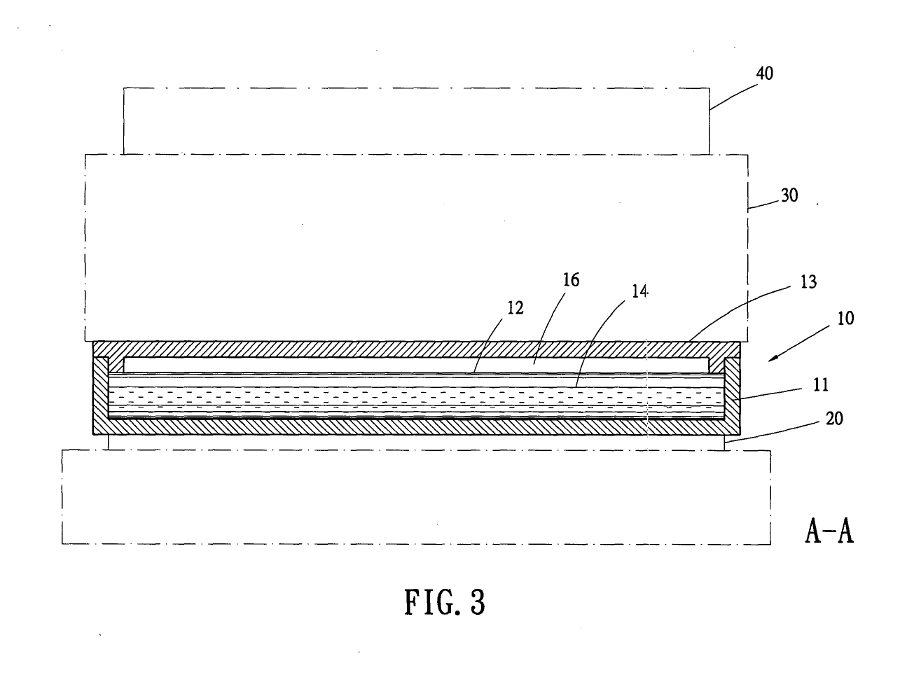

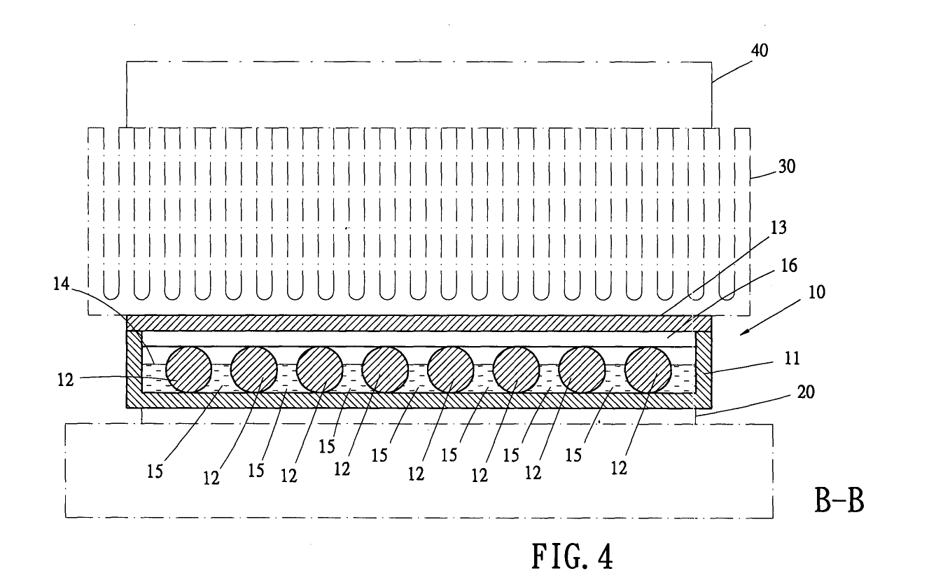

Referring simultaneously to FIGS. 3 and 4, the strip members 12 provided in the base 11 are strip-like structure portions with their sections wider in the middles and tapering to the top and bottom ends thereof; the strip members 12 are mutually parallelly provided in the bottom area of the base 11, flow channels 15 are formed from the strip members 12 on the bottom of the latter and are mutually spaced for flowing therethrough of the liquid 14; in flowing, the liquid 14 can rapidly move to form capillarity along the flow channels 15; a return area 16 is formed between the tops of the strip members 12 and the lid 13; thereby a completed structure of the heat conductive seat 10 is formed. Certainly, the lid 13 of the heat conductive seat 10 can be integrally formed with the heat sink 30 in order that the heat conductive seat 10 and the heat sink 30 can be combined structurally.

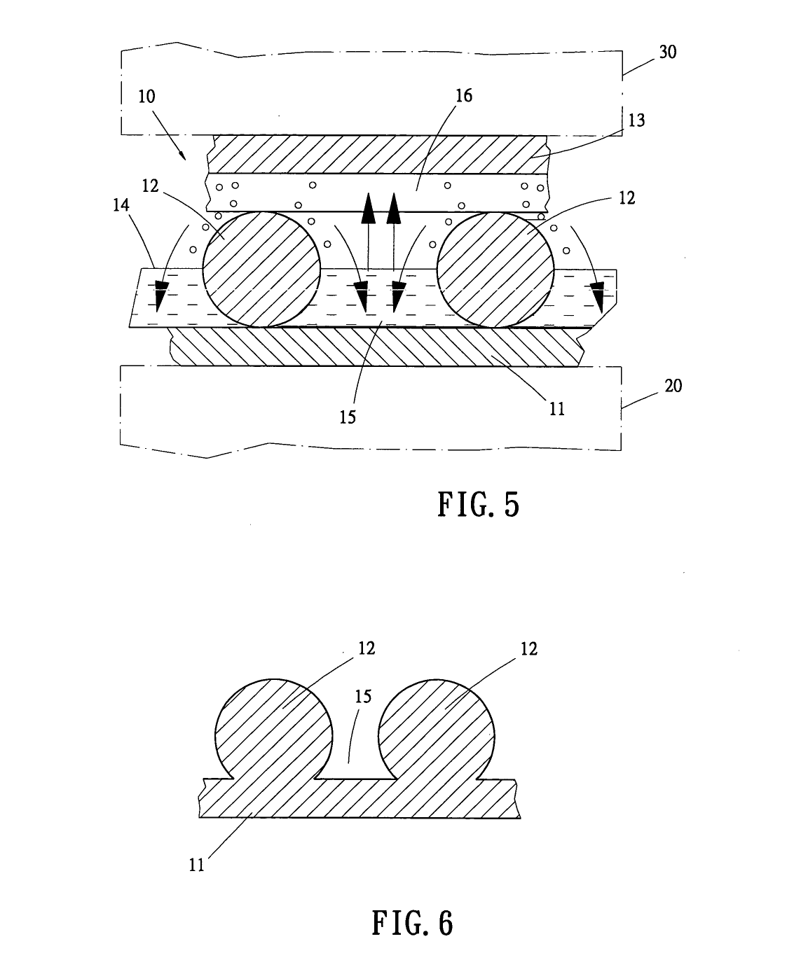

As shown in FIGS. 1, 3 and 4, in practical using of the heat conductive seat 10, the bottom of the base 11 contacts with the heat-generating source 20, and the lid 13 on the top of the base 11 contacts with the heat sink 30, the liquid 14 sealed in the base 11 and absorbing the latent heat from the heat-generating source 20 becomes a vapor flow flowing toward the return area 16, such as is shown in FIG. 5; when the vapor flow uniformly returns to the contact areas of the heat sink 30 with the heat conductive seat 10, it condenses by heat discharging into liquid and drops into the flow channels 15 to repeatedly circulate and transmit the heat, and the heat obtained from the heat-generating source 20 is rapidly and uniformly transmitted to the heat sink 30 to further increase the effect of heat sinking.

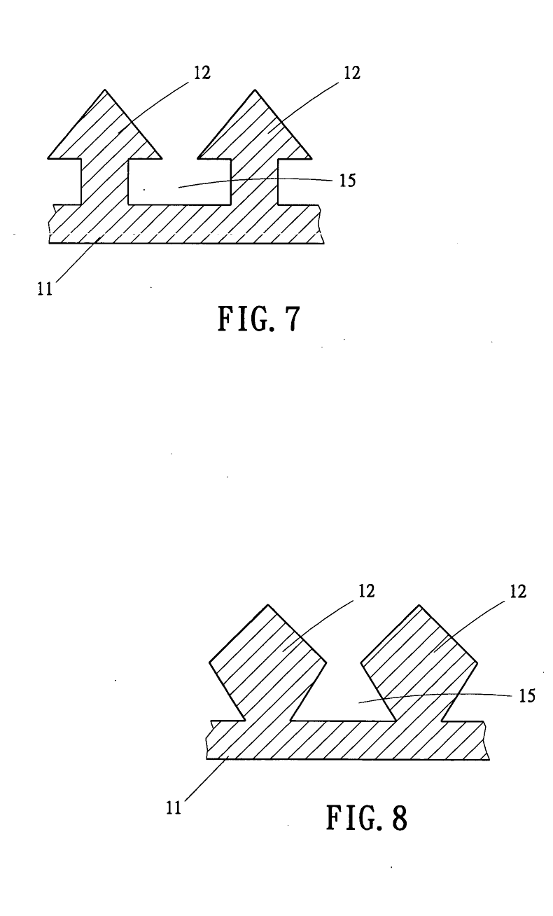

Particularly, the strip members 12 are strip-like structure portions with their sections wider in the middles and tapering to the top and bottom ends thereof; such as is shown in FIG. 5, the strip members 12 can be arranged in the bottom area in the base 11 in the form of metallic wires with round sections; or as is shown in FIG. 6, they can be integrally formed in the bottom area in the base 11 in the form structurally of strips with round sections; or even as is shown in FIGS. 7, 8, they can be integrally formed in the bottom area in the base 11 in the form of strips with arrow shaped sections, or in the form of strips with spearhead shaped sections. All these shapes can form strips with sections wider in the middles and tapering to the top and bottom ends thereof; so that when the vapor flow flows toward the area with lower temperature on the top of the base 11, it can be transversely transmitted by the flow channels 15 of the strip members 12 to the area with lower temperature, and the liquid formed by condensing by heat discharging can smoothly drops into the flow channels 15 by having the sectional conformation of the strip members 12, and rapidly flows to an area of high temperature, thereby, the object of transmitting heat to make uniform temperature can be obtained.

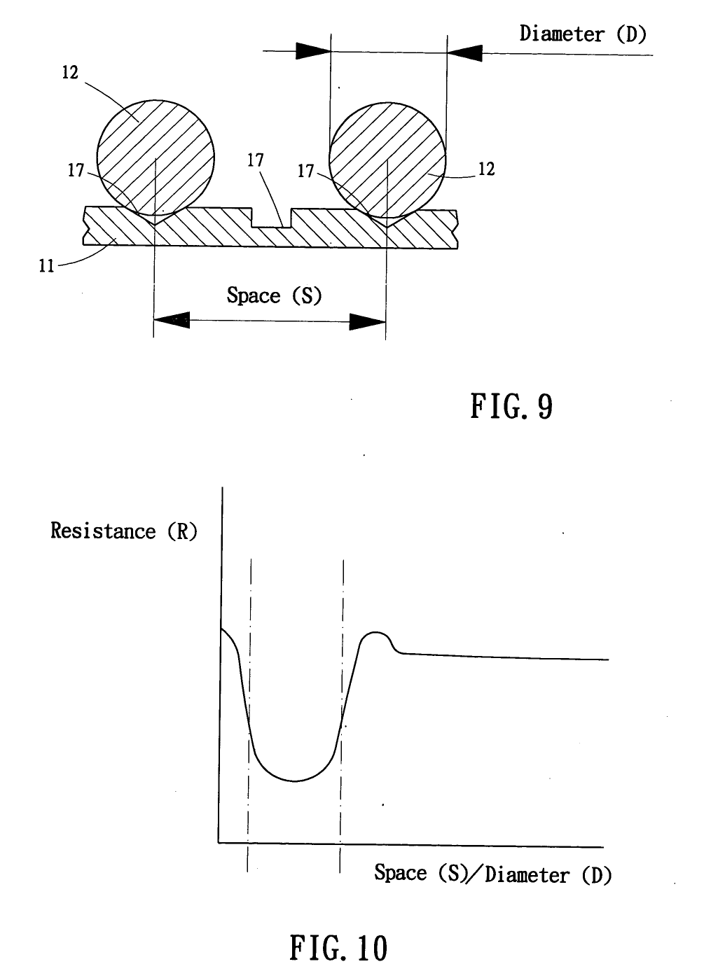

FIGS. 9 and 10 show the conformation and condition of allocation of the strip members 12 as well as a diagram showing a curve of efficiency of heat transmission obtained from various conditions in operation of the present invention; in FIG. 10, “R” represents thermo resistance, and at the lower positions of the curve, good efficiency of heat transmission can be obtained, this further discloses the best combinations of construction and allocation of the strip members in practicing.

And by virtue that the principal mechanical structure of the entire heat conductive seat 10 of the present invention is like that as shown in FIG. 2, it is formed by covering the lid 13 on the base 11 provided therein with the strip members 12 and the liquid 14, thereby as shown in FIG. 9, recesses 17 can be provided at the positions along and between the strip members 12 arranged in the bottom area of the base 11 to respectively form a function of positioning for the strip members 12 and to increase the action of guiding the liquid flow.

The above stated is only for illustrating preferred embodiments of the present invention, and not for giving any limitation to the scope of the present invention. It will be apparent to those skilled in this art that various modifications or changes without departing from the spirit of this invention shall also fall within the scope of the appended claims.

1. A heat conductive seat with liquid therein, said conductive seat has a recessed box like base as a main body thereof, a lid is provided to cover said base adapted to mounting thereon a heat sink, said base is sealed therein with liquid; said conductive seat is characterized by that:
said base is fixedly provided therein with a plurality of strip members, said strip members are strip-like structure portions with their sections wider in the middles and tapering to the top and bottom ends thereof; said strip members are mutually parallelly provided in a bottom area of said base, a plurality of flow channels are formed from said strip members on the bottom of said strip members and are mutually spaced; a return area is formed between said top ends of said strip members and said lid; when the bottom of said base contacts with a heat-generating source, said liquid sealed in said base and absorbing latent heat from said heat-generating source becomes a vapor flow flowing toward said return area and condenses by heat discharging into liquid and drops into said flow channels to repeatedly circulate and transmit said heat, thereby a heat source formed from said heat-generating source is rapidly transmitted.

2. The heat conductive seat with liquid therein as in claim 1, wherein:
said strip members arranged in said bottom area in said base are in the form of metallic wires with round sections.

3. The heat conductive seat with liquid therein as in claim 1, wherein:
said strip members arranged in said bottom area in said base are integrally formed in said bottom area in the form structurally of strips with round sections.

4. The heat conductive seat with liquid therein as in claim 1, wherein: said strip members arranged in said bottom area in said base are integrally formed in said bottom area in the form of strips with arrow shaped sections.

5. The heat conductive seat with liquid therein as in claim 1, wherein: said strip members arranged in said bottom area in said base are integrally formed in said bottom area in the form of strips with spearhead shaped sections.

6. The heat conductive seat with liquid therein as in claim 1, wherein: recesses are provided at the positions along said strip members arranged in said bottom area of said base to form a function of positioning for said strip members.

7. The improved heat sink structure as in claim 1, wherein: recesses are provided between the positions of said strip members arranged in said bottom area of said base to increase action of guiding flow of said liquid.

8. The heat conductive seat with liquid therein as in claim 1, wherein: said lid of said heat conductive seat is integrally formed with said heat sink in order that said heat conductive seat and said heat sink are combined structurally.
